(19) United States
(12) Patent Application Publication
(10) Pub. No.: US 2013/0063943 A1
(43) Pub. Date: Mar. 14, 2013

(54) INVERTER UNIT PROTECTIVE COVER FOR LIGHTING DEVICE, LIGHTING DEVICE FOR DISPLAY DEVICE, DISPLAY DEVICE, AND TELEVISION DEVICE

(71) Applicant: Shiyoshi Cho, Osaka (JP)

(72) Inventor: Shiyoshi Cho, Osaka (JP)

(73) Assignee: SHARP KABUSHIKI KAISHA, Osaka (JP)

(21) Appl. No.: 13/697,603

(22) PCT Filed: Apr. 25, 2011
(86) PCT No.: PCT/JP2011/060022

§ 371 Date: Nov. 13, 2012

(30) Foreign Application Priority Data
Jun. 3, 2010 (JP) 2010-127999

(51) Int. Cl. H05K 7/00; F21V 21/00

(52) U.S. Cl. 362/249.01; 174/50; 361/679.01

(57) ABSTRACT

An inverter unit protective cover for a lighting device configured to enhance versatility with low cost is provided. An inverter unit protective cover for a lighting device according to the present invention is an inverter unit protective cover for a lighting device protecting an inverter unit attached to the lighting device in which a plurality of light sources is housed in a chassis and includes a cover main body including a ceiling portion covering a side of the inverter unit away from the chassis and a circumferential wall portion covering a circumference of the inverter unit. The cover main body is formed in a sheet shape and made of an insulating material. The cover main body has a folding guide line at a border between the ceiling portion and the circumferential wall portion.

### TECHNICAL FIELD

The present invention relates to an inverter unit protective cover for a lighting device, a lighting device for a display device, a display device, and a television receiver.

### BACKGROUND ART

A device using a display panel that does not emit light such as a display device of a liquid crystal television set generally includes a lighting device that exits light to the display panel. The lighting device includes light sources such as a plurality of fluorescent lamps (e.g., cold cathode tubes) and a chassis housing the fluorescent lamps and the like and opened on a side of the display panel. On an outer side of the chassis is provided a light source driving unit (inverter unit) turning on the light sources. The inverter unit is a unit circuit in which an electronic component such as a transformer is mounted on an inverter board.

Such a lighting device generally includes a protective cover protecting the inverter unit at the time of transportation (e.g., Patent Document 1). This protective cover is made of a metal and is formed in a cover shape including a ceiling wall covering a side of the inverter unit opposite to the chassis and a circumferential wall covering a circumference of the inverter unit. Contact between a conductor and the transformer may adversely affect electric matters. Therefore, a part of the protective cover corresponding to the transformer has a window.

### Patent Document 1

Japanese Unexamined Patent Publication No. 2009-224308

### Problem to be Solved by the Invention

The protective cover structured as above needs to be formed in a different shape for each inverter unit such as changing a shape of the window in accordance with a shape or a position of the transformer. Thus, if an inverter unit is different, a protective cover must be formed in accordance with the inverter unit even in a case where a screen size is equal. Accordingly, even in a case where the inverter unit is changed for the purpose of cost reduction, the protective cover must be newly formed, and this fails in sufficient cost reduction.

Enhancement of versatility of the protective cover is considered by forming the protective cover by a resin material or the like that does not adversely affect the electric matters in case of contact between the conductor and the transformer. However, forming the three-dimensional protective cover by the resin material requires a complicated die, which causes a problem of a further cost increase than in a case of forming the metallic protective cover.

### DISCLOSURE OF THE PRESENT INVENTION

The present invention was made in view of the foregoing circumstances. An object of the present invention is to provide an inverter unit protective cover for a lighting device configured to enhance versatility with low cost.

### Means for Solving the Problem

An inverter unit protective cover for a lighting device according to the present invention protects an inverter unit attached to the lighting device in which a plurality of light sources is housed in a chassis and includes a cover main body formed in a sheet made of an insulating material and having a folding guide line. The cover main body includes a ceiling portion covering a side of the inverter unit away from the chassis and a circumferential wall portion covering a circumference of the inverter unit. The folding guide line is formed at a border between the ceiling portion and the circumferential wall portion.

According to this configuration, by folding the cover main body formed in a sheet shape along the guide line, the cover main body can be formed in a three-dimensional shape having the ceiling portion and the circumferential wall portion. In this context, since forming the insulating material in a sheet shape (flat shape) does not require a complicated die as in a case of forming a three-dimensional shape, low cost can be achieved.

Also, the cover main body that is made of an insulating material does not adversely affects electric matters even if contacting the inverter unit. Thus, a window is not required to be formed in accordance with a shape of the inverter unit, and a common cover main body can be used for different kinds of inverter units.

Accordingly, with this configuration, it is possible to enhance versatility with low cost.

Also, the guide line may include a plurality of guide lines that are provided at a plurality of positions to correspond to the inverter unit of a different kind and a different size selectively. According to this configuration, if the inverter unit is reduced in size, for example, selecting a folding position in accordance with a size of the inverter unit can achieve thinning of the lighting device.

Also, the inverter unit may include an inverter board and a transformer mounted on the inverter board, and the circumferential wall portion may include a high voltage side protective portion covering a portion of a circumferential edge of the inverter board that is closest to a mounting position of the transformer. Since this configuration enables reliable protection of a high voltage portion of the inverter unit, the inverter unit protective cover can be excellent in insulation.

Also, the inverter unit protective cover for a lighting device may further include a metal foil arranged on a surface opposite to a surface of the cover main body facing the inverter unit and a metallic screw fixing the metal foil to the chassis. According to this configuration, since the metal foil arranged on the surface of the cover main body is conductively connected to the chassis by the metallic screw, enhancement of grounding and enhancement of shielding can be achieved.

Also, the cover main body may be provided with a heat discharging window. Since this configuration restricts accumulation of heat inside the inverter unit protective cover, a temperature of the inverter unit is less likely to increase.

Also, the cover main body may be provided with a through hole in which a screw is inserted to fix the cover main body to the chassis.

Also, the cover main body may be provided with an inserting piece that is inserted to a recess formed in the chassis such that the cover main body is locked to the chassis. With this configuration a tightening member that attaches the cover main body to the chassis is not required, and this reduces the number of parts and this also reduces management cost.

A lighting device for a display device according to the present invention includes a plurality of light sources, a chassis housing the plurality of light sources, an inverter unit attached to the chassis and driving the plurality of light sources, and the inverter unit protective cover protecting the aforementioned inverter unit.

A display device according to the present invention includes the aforementioned lighting device for a display device and a display panel using light from the lighting device for a display device for display.

Also, the display panel may be a liquid crystal panel using liquid crystal.

A television device according to the present invention includes the aforementioned display device.

### Advantageous Effect of the Invention

The present invention can provide an inverter unit protective cover for a lighting device configured to enhance versatility with low cost.

### BRIEF DESCRIPTION OF THE DRAWINGS

FIG. 1 is an exploded perspective view illustrating a schematic configuration of a television device according to one embodiment;

FIG. 2 is an exploded perspective view illustrating a schematic configuration of a liquid crystal display device;

FIG. 3 is a cross-sectional view illustrating a cross-sectional configuration along a long side direction of the liquid crystal display device;

FIG. 4 is a cross-sectional view illustrating a cross-sectional configuration along a short side direction of the liquid crystal display device;

FIG. 5 is a plan view of an inverter unit protective cover before a cover main body is folded;

FIG. 6 is a partially enlarged cross-sectional view illustrating a configuration of the inverter unit protective cover that is made by folding the cover main body along first guide lines and attached to a chassis;

FIG. 7 is a partially enlarged cross-sectional view illustrating a configuration of the inverter unit protective cover that is made by folding the cover main body along second guide lines and attached to the chassis;

FIG. 8 is a partially enlarged cross-sectional view illustrating a configuration of the inverter unit protective cover according to another embodiment (1) attached to the chassis;

FIG. 9 is a plan view illustrating a configuration of an inverter unit protective cover according to another embodiment (2) before a cover main body is folded;

FIG. 10 is a partially enlarged cross-sectional view illustrating a configuration of the inverter unit protective cover that is made by folding the cover main body and attached to the chassis; and

FIG. 11 is a partially enlarged cross-sectional view illustrating a configuration of an inverter unit protective cover according to another embodiment (3) attached to the chassis.

### BEST MODE FOR CARRYING OUT THE INVENTION

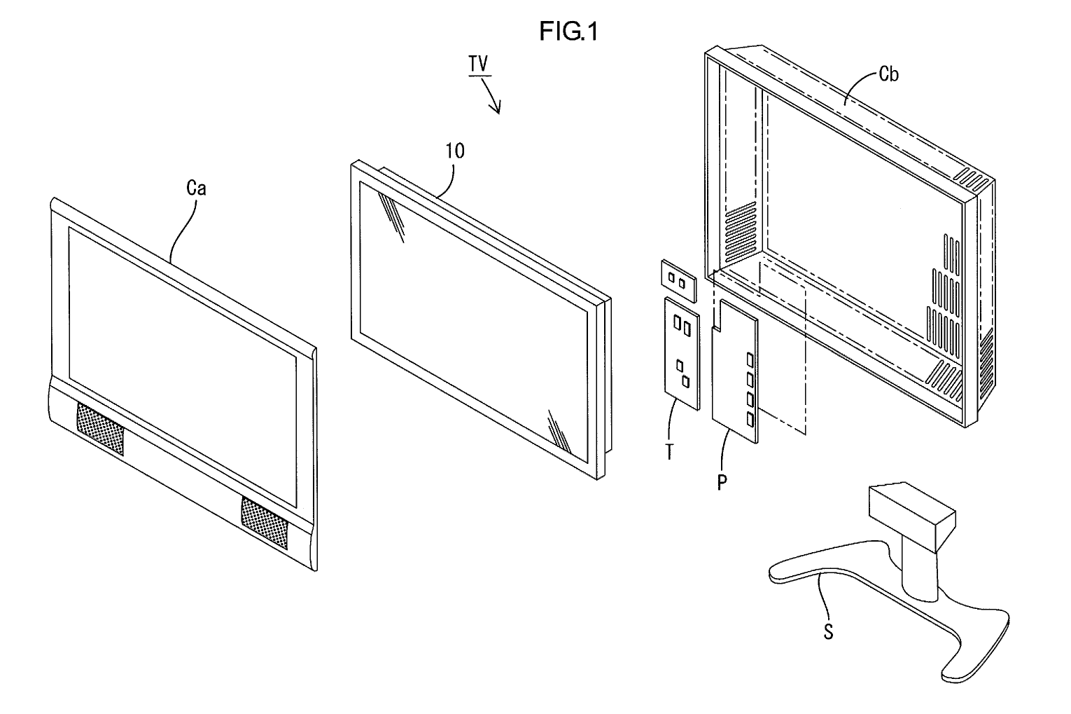

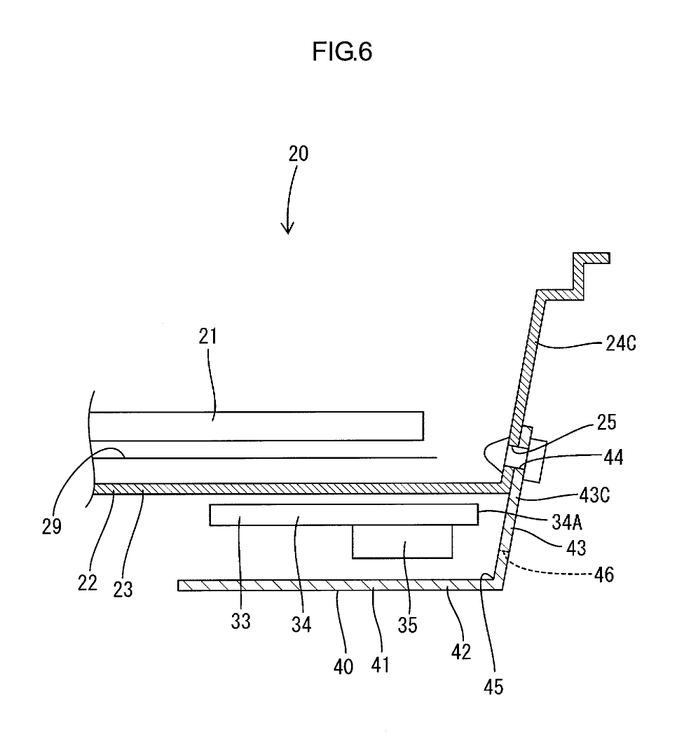

Hereinafter, an embodiment of the present invention will be described in details with reference to FIGS. 1 to 7. In the present embodiment, a television device TV including a liquid crystal display device 10 will be illustrated.

The television device TV according to the present embodiment is configured includes the liquid crystal display device 10, front and rear cabinets Ca and Cb housing the liquid crystal display device 10 so as to sandwich the liquid crystal display device 10 inbetween, a power source P, a tuner T receiving a television broadcast, and a stand S, as illustrated in FIG. 1. Hereinafter, in respective components, the lower left side in FIG. 1 (the front side or the display side of the television receiver TV) is referred to as a front side, the upper right side is referred to as a back side, the upper side is referred to as an upper side, and the lower side is referred to as a lower side.

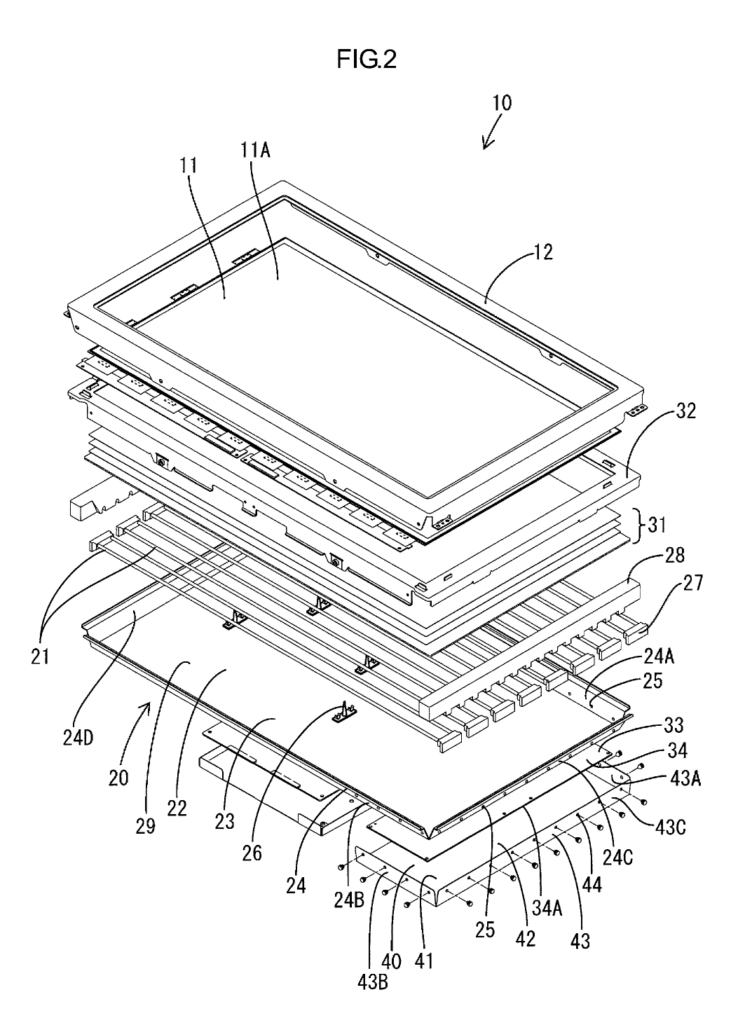

As illustrated in FIG. 2, the liquid crystal display device 10 includes a liquid crystal panel 11 and a lighting device 20 as an external light source such that these may be held integrally by a bezel 12 or the like. In the present embodiment, the liquid crystal display device 10 is formed in a horizontally long square shape as a whole and is used in a vertically-placed state or in a state in which a panel surface 11A (display surface) of the liquid crystal panel 11 is approximately parallel to a vertical direction.

The liquid crystal panel 11 has a configuration in which glass substrates as a pair are attached to each other in a state of leaving a predetermined gap and in which liquid crystal is filled between the glass substrates. One glass substrate is provided with switching components (such as TFTs) connected to source lines and gate lines perpendicular to each other, pixel electrodes connected to the switching components, and the like while the other glass substrate is provided with counter electrodes, color filters having respective color sections such as R, G, and B arranged in a predetermined array, and the like.

The lighting device 20 is the so-to-speak direct type lighting device 20 and includes a plurality of light sources (cold cathode tubes 21 are used as high-pressure discharge tubes here) at positions directly below a back surface of the panel surface 11A of the liquid crystal panel 11.

The lighting device 20 includes a chassis 22 having an upper surface side opened and formed in a shallow and approximately a box-like shape. The chassis 22 is made of a metal plate and includes a rectangular bottom plate 23 and a side plate 24 rising to the front side from a circumference of the bottom plate 23. The side plate 24 includes an upper side plate 24A arranged on an upper side in the vertical direction at the time of use of the liquid crystal display device 10, a lower side plate 24B arranged on a lower side, a right side plate 24C arranged on a right side as one faces the panel surface 11A, and a left side plate 24D arranged on a left side. The side plate 24 rises to be inclined obliquely outward from the bottom plate 23 (inclined to extend gradually outward from an outer edge of the bottom plate 23 toward the front side).

The upper side plate 24A, the lower side plate 24B, and the right side plate 24C of the side plate 24 are provided with screw holes 25 in which an after-mentioned inverter unit protective cover 40 is screwed shut. The plurality of screw holes 25 are provided at end portions of the upper side plate 24A and the lower side plate 24B closer to a side of the right side plate 24C and an entire portion of the right side plate 24C. The screw holes 25 are formed to be arranged approximately at regular pitches along longitudinal directions of the respective side plates 24A, 24B, and 24C in a row at positions on the respective side plates 24A, 24B, and 24C having approximately equal distances from the bottom plate 23 (height dimensions from the bottom plate 23 in a front-back direction).

In the chassis 22 are provided the cold cathode tubes 21, lamp clips 26 attaching the cold cathode tubes 21 to the chassis 22, lamp holders 27 supporting end portions of the cold cathode tubes 21, and holders 28 collectively covering the end portions of the cold cathode tubes 21 and the lamp holders 27 (refer to FIG. 2).

The cold cathode tubes 21 are formed in elongated tubular shapes and are housed in the chassis 22 to be arranged approximately parallel with one another such that length directions thereof (axial directions) aligned with a longitudinal direction of the chassis 22. Each of the cold cathode tubes 21 is held by the lamp clips 26 to have a space slightly from the chassis 22. Each of the lamp clips 26 is made of white synthetic resin. The bottom plate 23 of the chassis 22 is approximately parallel to the liquid crystal panel 11.

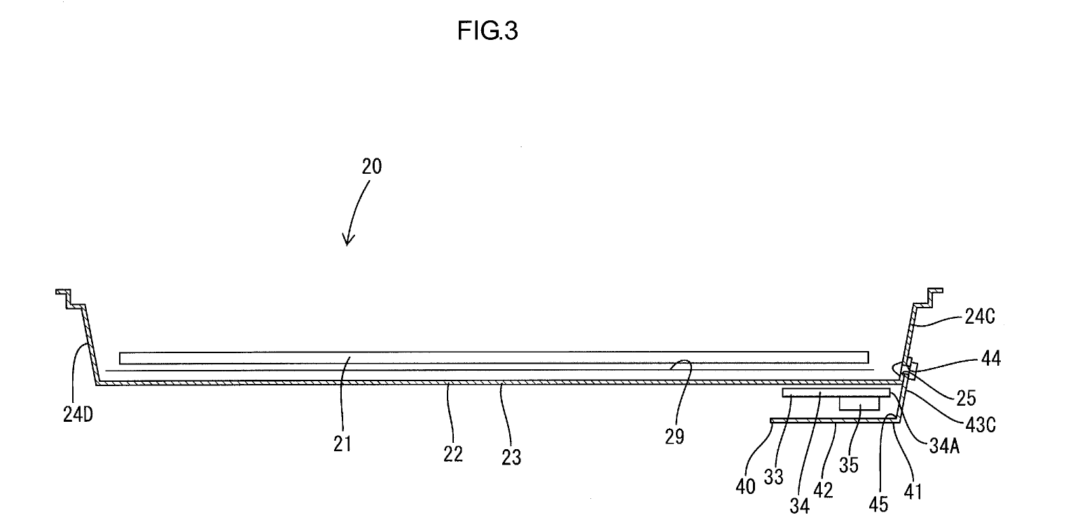

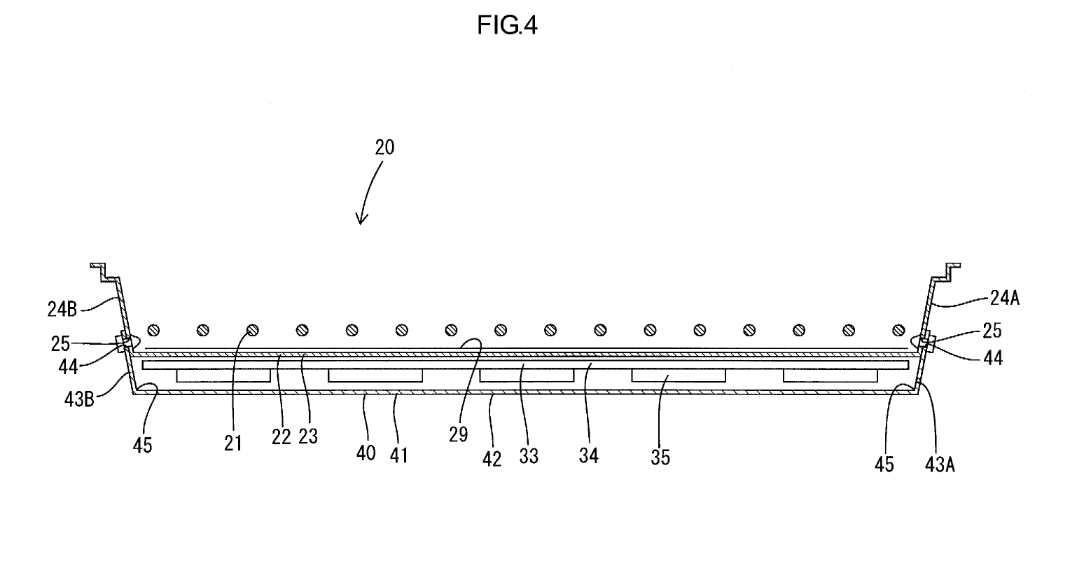

On an inside surface side of the bottom plate 23 of the chassis 22 (side opposite to a light outgoing side of the cold cathode tubes 21) is disposed a reflection sheet 29 (refer to FIGS. 3 and 4). The reflection sheet 29 is made of a synthetic resin and has a white surface excellent in light reflectance. The reflection sheet 29 is laid to cover approximately an entire area along the inside surface of the chassis 22, is integrated, and constitutes a wall surface (light reflection surface) of the chassis 22.

Each of the holders 28 is white, is made of a synthetic resin, and is formed in an elongated and approximately-box-like shape extending along a lateral direction of the chassis 22.

An optical member 31 is attached to cover an opening of the chassis 22. The optical member 31 includes a diffuser plate, a diffuser sheet, a lens sheet, and an optical sheet in this order from the lower side (a side of the chassis 22) in FIG. 2.

On a front surface side of the optical member 31 is installed a metallic frame 32 holding the optical member 31 in the chassis 22. The frame 32 is formed in an approximately square frame shape along a circumferential portion of the optical member 31.

On a back surface of the chassis 22 (outer surface of a side opposite to a side on which the cold cathode tubes 21 are arranged) is attached an inverter unit 33 driving and controlling the cold cathode tubes 21. The inverter unit 33 functions to control lighting and extinction of the cold cathode tubes 21 by raising input voltage input from the power source P of the liquid crystal display device 10 and outputting output voltage higher than the input voltage to the cold cathode tubes 21.

The inverter unit 33 is provided only on one end side of the chassis 22 in a longer side direction and is electrically connected to one end portion of each cold cathode tube 21 by a terminal (not shown) for the purpose of supplying drive voltage to one end portion of each cold cathode tube 21.

The inverter unit 33 includes an inverter board 34 and electronic components such as transformers 35. The inverter board 34 is made of a synthetic resin (e.g., phenolic paper and glass epoxy resin) and is formed in an approximately rectangular plate shape in a planar view. The inverter board 34 has predetermined wiring patterns on its front and back surfaces and has various electronic components mounted thereon. A length dimension of a longer side of the inverter board 34 is equal to or slightly shorter than a length dimension of a shorter side of the bottom plate 23 of the chassis 22 (refer to FIG. 4).

On one surface out of the front and back surfaces of the inverter board 34 (surface located on a side opposite to the chassis 22 in a state where the inverter board 34 is attached to the chassis 22) is mounted the plurality of transformers 35 generating radio frequency voltage as drive voltage to the cold cathode tubes 21. The plurality of transformers 35 is arranged in line along the longer side of the inverter board 34 (refer to FIG. 4) at positions closer to one end side in a shorter side direction of the inverter board 34 (positions closer to the right side in FIG. 3). The longer side along which the transformers 35 are arranged is a high voltage side 34A closest to mounting positions of the transformers 35 in a circumference of the inverter board 34. The high voltage side 34A is arranged on the right side in a state where the inverter unit 33 is attached to the chassis 22.

The inverter unit 33 is attached to the chassis 22 in a direction in which a surface opposite to a side on which the transformers 35 are mounted out of the front and back surfaces of the inverter board 34 is opposed to aback surface of the bottom plate 23 of the chassis 22 (surface opposite to the cold cathode tubes 21). The inverter unit 33 is also fixed on the bottom plate 23 by screws or the like in a direction in which the longer side direction of the inverter board 34 is aligned with the shorter side direction of the chassis 22 and in which the high voltage side 34A is arranged in proximity to one end in the longer side direction of the chassis 22. In a state in which the inverter unit 33 is attached to the chassis 22, a plate surface of the inverter board 34 and a plate surface of the bottom plate 23 are approximately parallel to each other.

The inverter unit 33 is protected by the inverter unit protective cover 40. The inverter unit protective cover 40 is made of an insulating synthetic resin material and is formed in a sheet shape. The inverter unit protective cover 40 is formed in a three-dimensional shape at the time of being attached to the chassis 22.

First, a configuration of the inverter unit protective cover 40 that is folded three-dimensionally will be described. The inverter unit protective cover 40 includes a cover main body 41 covering approximately the entirety of the inverter unit 33. The cover main body 41 is formed in a shallow box shape opened on a front side (a side of the bottom plate 23 when the inverter unit protective cover 40 is attached to the chassis 22) and on a left side (a side opposite to the right side plate 24C when the inverter unit protective cover 40 is attached to the chassis 22) (refer to FIG. 3).

The cover main body 41 includes a ceiling portion 42 covering a rear side of the inverter unit 33 (side on which the transformer 35 is mounted) and a circumferential wall portion 43 covering a circumference of the inverter unit 33.

The ceiling portion 42 is formed in a rectangular shape in a planar view which is one size larger than the inverter board 34. A length dimension of a shorter side of the ceiling portion 42 is equal to or slightly longer than a length dimension of a shorter side of the inverter board 34 (refer to FIG. 3). Also, a length dimension of a longer side of the ceiling portion 42 is equal to or slightly longer than a length dimension of a shorter side of the chassis 22 (refer to FIG. 4).

The circumferential wall portion 43 rises to the front side from three edges (two longer sides and one shorter side) out of circumferential edges of the ceiling portion 42.

The circumferential wall portion 43 includes an upper side protective portion 43A and a lower side protective portion 43B covering an upper side and a lower side of the inverter unit 33, respectively (a right side and a left side in FIG. 4) and a high voltage side protective portion 43C covering a right side of the inverter unit 33 (a right side in FIG. 3).

Each of the upper side protective portion 43A and the lower side protective portion 43B is formed in an approximately rectangular plate shape, and a rising dimension of each of the upper side protective portion 43A and the lower side protective portion 43B from the ceiling portion 42 is uniform along the shorter side direction of the ceiling portion 42. Also, a length dimension of a longer side of each of the upper side protective portion 43A and the lower side protective portion 43B is equal to the length dimension of the shorter side of the ceiling portion 42. The upper side protective portion 43A and the lower side protective portion 43B are approximately equal in shape and size and are opposed in the up-down direction with the ceiling portion 42 inbetween.

Also, the high voltage side protective portion 43C covers a lateral side (right side) of the high voltage side 34A (refer to FIG. 3). The high voltage side protective portion 43C is formed in an elongated, approximately-rectangular plate shape along the longer side of the ceiling portion 42, and a rising dimension of the high voltage side protective portion 43C from the ceiling portion 42 is uniform along the longer side direction of the ceiling portion 42 and equal to the rising dimension of each of the upper side protective portion 43A and the lower side protective portion 43B from the ceiling portion 42. Also, a length dimension of a longer side of the high voltage side protective portion 43C is equal to the length dimension of the longer side of the ceiling portion 42.

In the circumferential wall portion 43 of the inverter unit protective cover 40 are formed through holes 44 at positions corresponding to the screw holes 25 formed in the side plate 24 of the chassis 22. The inverter unit protective cover 40 is set to the chassis 22 such that the through holes 44 may be connected to outsides of the screw holes 25 of the chassis 22 and a screw is inserted through the through hole 44 and the screw hole 25 and the inverter unit protective cover 40 is fixed to the chassis 22.

Next, a configuration of the inverter unit protective cover 40 before being folded three-dimensionally will be described.

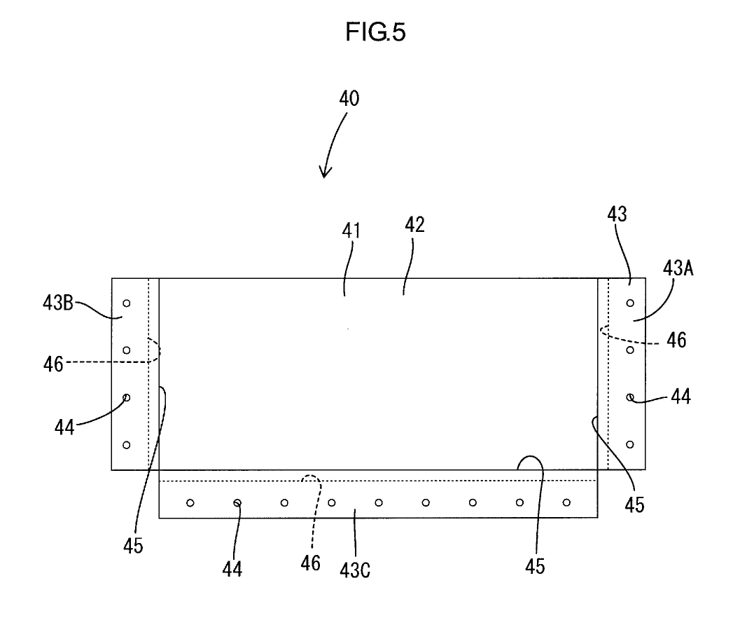

The cover main body 41 of the inverter unit protective cover 40 is formed in a sheet shape having an approximately uniform thickness dimension entirely as illustrated in FIG. 5.

Parts of the inverter unit protective cover 40 that will become the upper side protective portion 43A and the lower side protective portion 43B when being folded along a first guide line 45 (hereinafter referred to simply as the upper side protective portion 43A and the lower side protective portion 43B) are provided continuously from the shorter sides of a part of the inverter unit protective cover 40 that will become the ceiling portion 42 when being folded along the first guide line 45 (hereinafter referred to simply as the ceiling portion 42). A part of the inverter unit protective cover 40 that will become the high voltage side protective portion 43C when being folded along the first guide line 45 (hereinafter referred to simply as the high voltage side protective portion 43C) is provided continuously from the longer side of the ceiling portion 42. A folding guide line (referred to as the first guide line 45) is provided at a border position between the upper side protective portion 43A and the ceiling portion 42, a border position between the lower side protective portion 43B and the ceiling portion 42, and a border position between the high voltage side protective portion 43C and the ceiling portion 42. Each first guide line 45 is a straight line extending linearly. The first guide line 45 as the border between the upper side protective portion 43A and the ceiling portion 42 and the first guide line 45 as the border between the lower side protective portion 43B and the ceiling portion 42 are approximately parallel to each other. Also, these two first guide lines 45 and the first guide line 45 as the border between the high voltage side protective portion 43C and the ceiling portion 42 are approximately perpendicular to each other.

The first guide lines 45 are lines enabling the upper side protective portion 43A, the lower side protective portion 43B, and the high voltage side protective portion 43C to be folded at least in one direction (one of a front surface side and a back surface side) with respect to the ceiling portion 42. Each of the first guide lines 45 can be formed in various methods such as making a cut along the border.

The cover main body 41 is provided with second guide lines 46 (illustrated by dashed lines in FIG. 5) in addition to the first guide lines 45 to correspond to inverter units 33 of a plurality of kinds having different sizes selectively. The second guide lines 46, as well as the first guide lines 45, are lines enabling the upper side protective portion 43A, the lower side protective portion 43B, and the high voltage side protective portion 43C to be folded at least in one side surface direction with respect to the ceiling portion 42.

The three second guide lines 46 in total are formed individually at borders between the upper side protective portion 43A and the ceiling portion 42, between the lower side protective portion 43B and the ceiling portion 42, and between the high voltage side protective portion 43C and the ceiling portion 42. Each of the second guide lines 46 provides the circumferential wall portion having a different size from the circumferential wall portion provided when being folded along the first guide line 45. Each of the second guide lines 46 is a line extending linearly and is formed outside (on an outer edge side of the cover main body 41) the proximate first guide line 45 and closer to the first guide line 45. The first guide line 45 and the second guide line 46 formed at borders between the upper side protective portion 43A and the ceiling portion 42, the first guide line 45 and the second guide line 46 formed at borders between the lower side protective portion 43B and the ceiling portion 42, and the first guideline 45 and the second guide line 46 formed at borders between the high voltage side protective portion 43C and the ceiling portion 42 are equally spaced from each other and approximately parallel to each other, respectively. The through holes 44 are formed at parts between outer edges of the upper side protective portion 43A, the lower side protective portion 43B, and the high voltage side protective portion 43C and the second guide lines 46, respectively.

In a case where the cover main body 41 is folded along the second guide lines 46, height dimensions of the upper side protective portion 43A, the lower side protective portion 43B, and the high voltage side protective portion 43C from the ceiling portion 42 are shorter than in a case where the cover main body 41 is folded along the first guide lines 45, and a width dimension of the ceiling portion 42 is longer than in the case where the cover main body 41 is folded along the first guide lines 45.

Next, a method of attaching the inverter unit protective cover 40 to the chassis 22 will be described.

The inverter unit protective cover 40 is formed in a sheet shape in a state before being attached to the chassis 22 as illustrated in FIG. 5.

First, the high voltage side protective portion 43C of the inverter unit protective cover 40 is overlapped with a right side of the right side plate 24C of the chassis 22 and is fixed thereto by a screw. After the inverter unit protective cover 40 is held on the chassis 22 in this manner, the inverter unit 33 is attached to the back side of the chassis 22.

Subsequently, the cover main body 41 is folded along the first guide lines 45, the upper side protective portion 43A is overlapped with an upper side of the upper side plate 24A, lower side protective portion 43B is overlapped with a lower side of the lower side plate 24B, such that the screw holes 25 and the through holes 44 may communicate with each other, and the cover main body 41 is fixed to the chassis 22 by a screw.

In this manner, attachment of the inverter unit protective cover 40 to the chassis 22 is completed, and the inverter unit protective cover 40 covers and protects approximately the entirety of a back side of the inverter unit 33. At this time, the ceiling portion 42 of the inverter unit protective cover 40 is approximately parallel to a ceiling surface of the inverter unit 33 (ceiling surface of the transformer 35), and these are in a state of being opposed to each other via a predetermined gap. Also, an angle formed between the circumferential wall portion 43 and the ceiling portion 42 of the inverter unit protective cover 40 is equal to an angle formed between the rectangular bottom plate 23 and the side plate 24 of the chassis 22, and the circumferential wall portion 43 and the side plate 24 are in a state of surface contact.

There is a case in which the inverter unit 33 is downsized for the purpose of cost reduction.

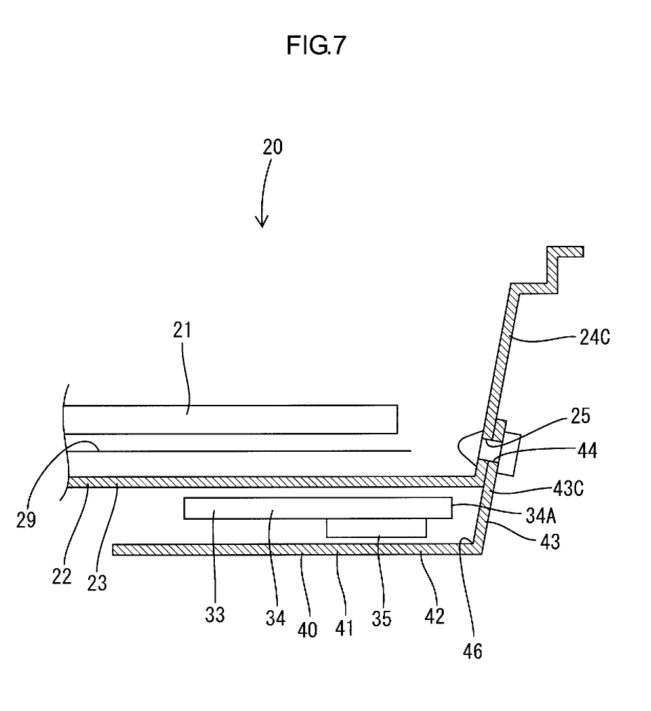

In this case, as illustrated in FIG. 7, the cover main body 41 of the inverter unit protective cover 40 is folded along the second guide lines 46 and is attached to the chassis 22. Accordingly, a height dimension of the circumferential wall portion 43 is shorter than in a case where the cover main body 41 is folded along the first guide lines 45, and the inverter unit protective cover 40 sizes to fit the inverter unit 33. Accordingly, even with use of the same inverter unit protective cover 40, the gap between the ceiling portion 42 and the ceiling surface of the inverter unit 33 is less likely to increase, and this achieves a thin liquid crystal display device 20.

The present embodiment configured as above exerts the following effects.

The inverter unit protective cover 40 according to the present embodiment is the inverter unit protective cover 40 for the lighting device 20 configured to protect the inverter unit 33 attached to the lighting device 20 in which the plurality of cold cathode tubes 21 is housed in the chassis 22 and includes the cover main body 41 including the ceiling portion 42 covering a side of the inverter unit 33 opposite to the chassis 22 and the circumferential wall portion 43 covering the circumference of the inverter unit 33. The cover main body 41 is formed in a sheet shape and made of an insulating material. The cover main body 41 has the first guide line 45 for folding at a border between the ceiling portion 42 and the circumferential wall portion 43.

Thus, by folding the cover main body 41 formed in a sheet shape along the first guide line 45, the cover main body 41 can be formed in a three-dimensional shape having the ceiling portion 42 and the circumferential wall portion 43. In this context, since forming the insulating material into a sheet shape (flat shape) does not require a complicated die as in a case of forming a three-dimensional shape, low cost can be achieved.

Also, the cover main body 41 that is made of the insulating material does not adversely affects electric matters even if contacting the inverter unit 33. Thus, a window is not required to be formed in accordance with a shape of the inverter unit 33, and a common cover main body can be used for different kinds of inverter units 33.

Accordingly, with the configuration according to the present embodiment, it is possible to enhance versatility with low cost.

Also, the second guide line 46 in addition to the first guide line 45 is provided to correspond to the inverter unit 33 of a different kind and a different size selectively. Thus, if the inverter unit 33 is reduced in size for example, selecting a folding position in accordance with a size of the inverter unit 33 can achieve thinning of the lighting device 20.

Also, the inverter unit 33 includes the inverter board 34 and the transformer 35 mounted on the inverter board 34, and the circumferential wall portion 43 includes the high voltage side protective portion 43C covering the lateral side of the high voltage side 34A of the inverter board 34. Since this enables reliable protection of a high voltage portion of the inverter unit 33, the inverter unit protective cover 40 can be excellent in insulation.

### <Other Embodiment>

The present invention is not limited to the above embodiments described in the above description. The following embodiments may be included in the technical scope of the present invention, for example.

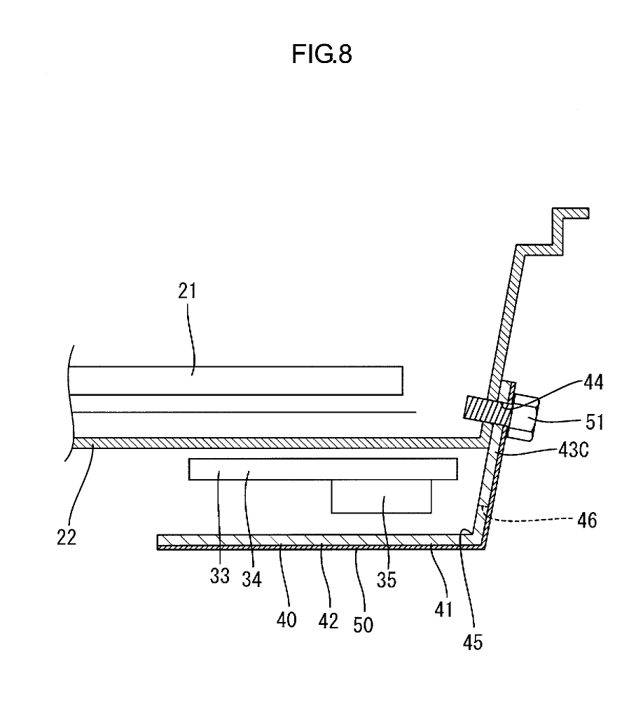

(1) The inverter unit protective cover 40 made of the insulating material is fixed to the chassis 22 by a screw in the above embodiment, and a metal foil 50 may be additionally arranged on an outside surface of the cover main body 41 (a surface opposite to a surface facing the inverter unit 33), and the metal foil 50 and the cover main body 41 may be fixed to the chassis 22 by a metallic screw 51 as illustrated in FIG. 8. With this configuration, since the metal foil 50 arranged on the entire surface of the cover main body 41 is conductively connected to the chassis 22 by the metallic screw 51, enhancement of grounding and of shielding can be achieved.

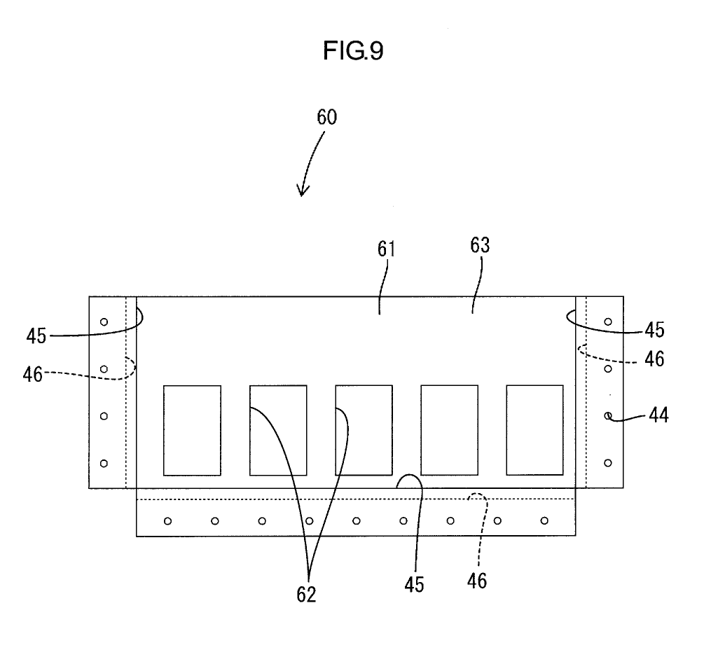

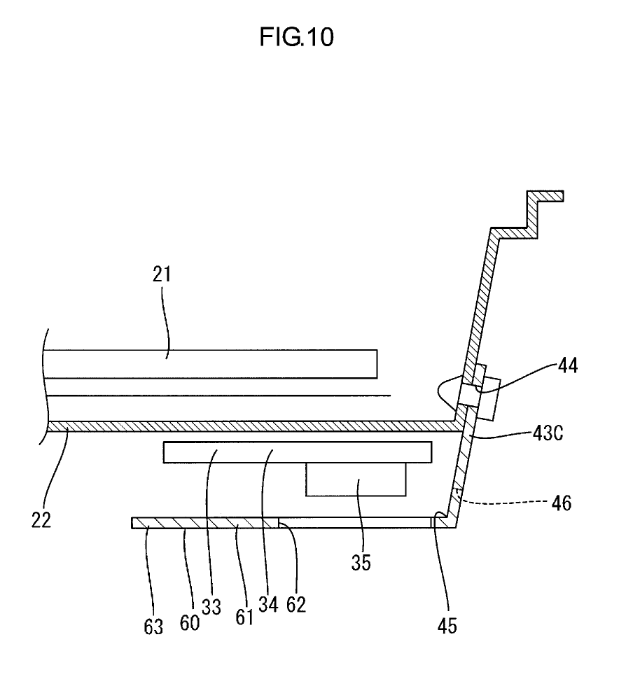

(2) The inverter unit protective cover 40 covers approximately the entirety of the inverter unit 33 in the above embodiment. A plurality of heat discharging windows 62 may be additionally formed in a cover main body 61 of an inverter unit protective cover 60 as illustrated in FIGS. 9 and 10. Since this restricts accumulation of heat inside the inverter unit protective cover 60, a temperature of the inverter unit 33 is less likely to increase. It is to be noted that the heat discharging windows 62 may be provided at any positions, and for example, the plurality of heat discharging windows 62 may be formed at parts opposed to the transformers 35 in a ceiling portion 63 of the cover main body 61.

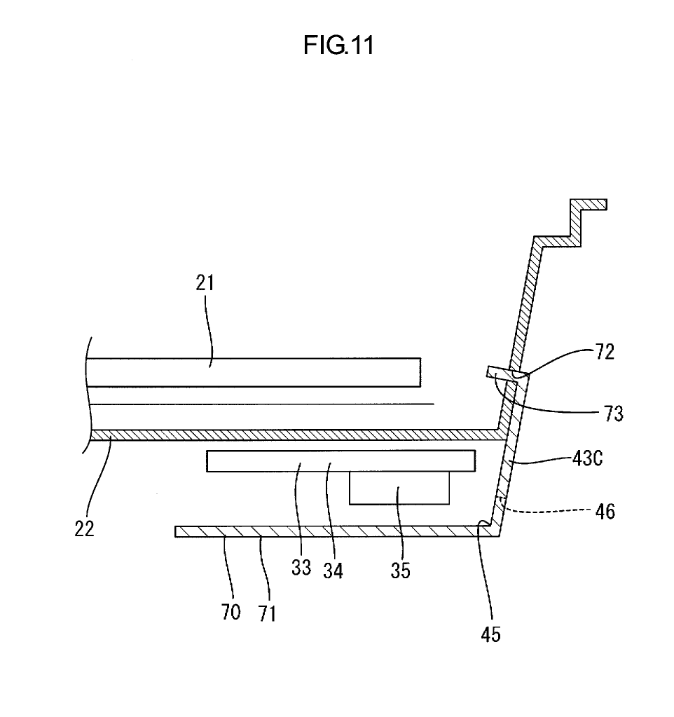

(3) The inverter unit protective cover 40 is fixed to the chassis 22 by a screw in the above embodiment. The embodiment is not limited to this, and for example, a cover main body 71 of an inverter unit protective cover 70 may be provided with an inserting piece 73. The inserting piece 73 may be inserted in an inserting recess 72 formed in the chassis 22 as illustrated in FIG. 11 to be fitted to the chassis 22. With this configuration, tightening members such as screws that attach the cover main body 71 to the chassis 22 are not required, and this reduces the number of parts and this reduces management cost.

(4) The second guide line 46 as well as the first guide lines 45 is formed in the above embodiment, and more guide lines such as a third guide line and a fourth guide line may be formed.

(5) The inverter unit 33 and the inverter unit protective cover 40 are attached only on one side in the longer side direction of the chassis 22 in the above embodiment, and they may be attached on both sides in the longer side direction of the chassis. In this case, drive voltage can be supplied to both end portions of each cold cathode tube from the inverter unit.

(6) In the above embodiment, the cold cathode tubes 21 are used as light sources, and light sources of another kind such as hot cathode tubes may be used.

(7) The liquid crystal display device 10 has been illustrated in the above embodiment, and the present invention can be applied to a display device using a lighting device other than the liquid crystal display device.

### EXPLANATION OF SYMBOLS

TV: Television device
10: Liquid crystal display device (Display device)
11: Liquid crystal panel (Display panel)
20: Lighting device
21: Cold cathode tube (Light source)
22: Chassis
33: Inverter unit
34: Inverter board
35: Transformer
40, 60, 70: Inverter unit protective cover
41, 61, 71: Cover main body
42, 63: Ceiling portion
43: Circumferential wall portion
43C: High voltage side protective portion
44: Through hole
45: First guide line
46: Second guide line
50: Metal foil
51: Metallic screw
62: Heat discharging window
72: Inserting recess
73: Inserting piece

1. An inverter unit protective cover for a lighting device protecting an inverter unit attached to the lighting device in which a plurality of light sources are housed in a chassis, the inverter unit protective cover comprising:
a cover main body formed in a sheet made of an insulating material and having a folding guide line, the cover main body including:
a ceiling portion covering a side of the inverter unit away from the chassis; and
a circumferential wall portion covering a circumference of the inverter unit,
wherein the folding guide line is formed at a border between the ceiling portion and the circumferential wall portion.

2. The inverter unit protective cover for a lighting device according to claim 1, wherein the guide line includes a plurality of guide lines that are provided at a plurality of positions to correspond to the inverter unit of a different kind and a different size selectively.

3. The inverter unit protective cover for a lighting device according to claim 1, wherein
the inverter unit includes an inverter board and a transformer mounted on the inverter board, and
the circumferential wall portion includes a high voltage side protective portion covering a portion of a circumferential edge of the inverter board that is closest to a mounting position of the transformer.

4. The inverter unit protective cover for a lighting device according to claim 1, further comprising:
a metal foil arranged on a surface opposite to a surface of the cover main body facing the inverter unit; and
a metallic screw fixing the metal foil to the chassis.

5. The inverter unit protective cover for a lighting device according to claim 1, wherein the cover main body is provided with a heat discharging window.

6. The inverter unit protective cover for a lighting device according to claim 1, wherein the cover main body is provided with a through hole in which a screw is inserted to fix the cover main body to the chassis.

7. The inverter unit protective cover for a lighting device according to claim 1, wherein the cover main body is provided with an inserting piece that is inserted to a recess formed in the chassis such that the cover main body is locked to the chassis.

8. A lighting device for a display device comprising:
a plurality of light sources;
a chassis housing the plurality of light sources;
an inverter unit attached to the chassis and driving the plurality of light sources; and
the inverter unit protective cover protecting the inverter unit according to claim 1.

9. A display device comprising:
the lighting device for a display device according to claim 8; and
a display panel using light from the lighting device for a display device for display.

10. The display device according to claim 9, wherein the display panel is a liquid crystal panel using liquid crystal.

11. A television device comprising:
the display device according to claim 9.
